(19) United States
(12) Patent Application Publication
(10) Pub. No.: US 2009/0288867 A1
(43) Pub. Date: Nov. 26, 2009

(54) CIRCUIT STRUCTURE AND PHOTOMASK FOR DEFINING THE SAME

(75) Inventors: Te-Hung Tu, Taipei City (TW); Kao-Tun Chen, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/102,876

(22) Filed: Apr. 15, 2008

(51) Int. Cl. H05K 1/11; G03F 1/00

(52) U.S. Cl. 174/261; 430/5

(57) ABSTRACT

A circuit structure and a photomask for defining the same are described. The circuit structure includes a plurality of pickup pads and a plurality of lines in parallel, in which a part of the lines arranged contiguously are each disposed with a pickup pad. The pickup pad of any line disposed with a pickup pad is connected, through a discontinuity of a neighboring line at one side of the line, to a next line. The photomask has thereon a plurality of line patterns for defining the above lines and a plurality of pickup pad defining patterns for defining the above pickup pads.

### BACKGROUND OF THE INVENTION

1. Field of Invention

This invention generally relates to integrated circuit (IC) design, in particular, to a circuit structure applied to the field of IC and to a photomask for defining the same of which the patterns are easier to correct with optical proximity correction (OPC).

2. Description of Related Art

In current semiconductor processes, a dog-bone pattern is usually taken as the photomask pattern for a pickup region of a line. Referring to the circuit design in FIG. 1, the position of a pickup pad pattern 120 for a line pattern 110 is between a dense region 12 and an isolated region 14. For there is a significant pattern density difference, it is difficult to control the optical proximity effects so that the OPC process is complex, as shown in FIG. 2, where the numerals 210 and 220 respectively indicate a line pattern and a pickup pad pattern. Therefore, the OPC usually has to be assisted by a computer, so as to achieve a better correction effect.

As the linewidth of lithography process is reduced, the optical proximity effect becomes more severe with the development of lithography techniques (for example, a shorter wavelength of exposure light or a larger numerical aperture, etc.). Therefore, the difficulty in OPC of the dog-bone design is further increased making a sufficiently large process window difficult to obtain.

### SUMMARY OF THE INVENTION

Accordingly, this invention provides a circuit structure that includes lines and pickup pads, of which the corresponding photomask patterns are easier to correct with OPC as compared with the prior art.

This invention also provides a photomask, which is suitable for defining a circuit structure of this invention. The OPC of the line patterns and the pad-defining patterns on the photomask is easier to apply as compared with the prior art.

The circuit structure of this invention includes a plurality of lines in parallel and a plurality of pickup pads. A part of the lines arranged contiguously are each disposed with a pickup pad. The pickup pad of any line disposed with a pickup pad is connected, through a discontinuity of a neighboring line at one side of the line, to a next line. Such a local structure including the pickup pad is particularly called an H-cut structure.

The photomask of the invention is for defining an above circuit structure, having a plurality of line patterns in parallel and a plurality of pickup pad defining patterns. A part of the line patterns arranged contiguously are each disposed with a pickup pad defining pattern. The pickup pad defining pattern of any line pattern disposed with a pickup pad defining pattern is disposed, through a discontinuity of a neighboring line pattern at one side of the line pattern, between a next line pattern and the line pattern.

In some embodiments, especially under a situation of smaller linewidth, the line patterns and the pickup pad defining patterns are further corrected through OPC. The OPC may be a simple symmetric OPC. In an embodiment, the pickup pad defining pattern connects with the next line pattern and the line pattern. The related OPC, for example, includes reducing the dimension of the pickup pad defining pattern in the extending direction of the line patterns, making the two inner boundaries and the two outer boundaries of two parts of the next line pattern and the line pattern respectively located at two sides of the pickup pad defining pattern respectively protrude outwards and shrink inwards, and make the two inner boundaries and the two outer boundaries of two parts of the two line patterns at the outer sides of the two line patterns at the outer sides of the next line pattern and the line pattern respectively located at the two sides of the pickup pad defining pattern both shrink inwards.

In the H-cut structure of this invention, the pattern density around a pickup pad defining pattern approaches that of the dense region so that the optical proximity effect is easier to control as compared with the conventional dog-bone design. Furthermore, as the H-cut structure has a good symmetry, the OPC can be implemented more easily. Through computer simulations and experiments, it was discovered that under the same condition of lithography, the H-cut pattern design of this invention makes a process window larger than that made by the conventional dog-bone pattern design.

In order to make the aforementioned and other objects, features and advantages of this invention comprehensible, a preferred embodiment accompanied with figures is described in detail below.

### BRIEF DESCRIPTION OF THE DRAWINGS

FIG. 1 shows a structure of a plurality of line patterns disposed with pickup pad patterns in the conventional dog-bone design.

FIG. 2 shows the result after a pickup pad pattern in the conventional dog-bone design and the near line patterns are corrected through OPC.

FIG. 3 shows a structure and a design process of a plurality of line patterns disposed with pickup pad patterns according to an embodiment of this invention.

FIG. 4 shows an example (a) of the OPC for forming a photomask pattern with an H-cut structure of this invention, and a computer simulation (b) of a circuit structure defined by the photomask pattern having been corrected through OPC.

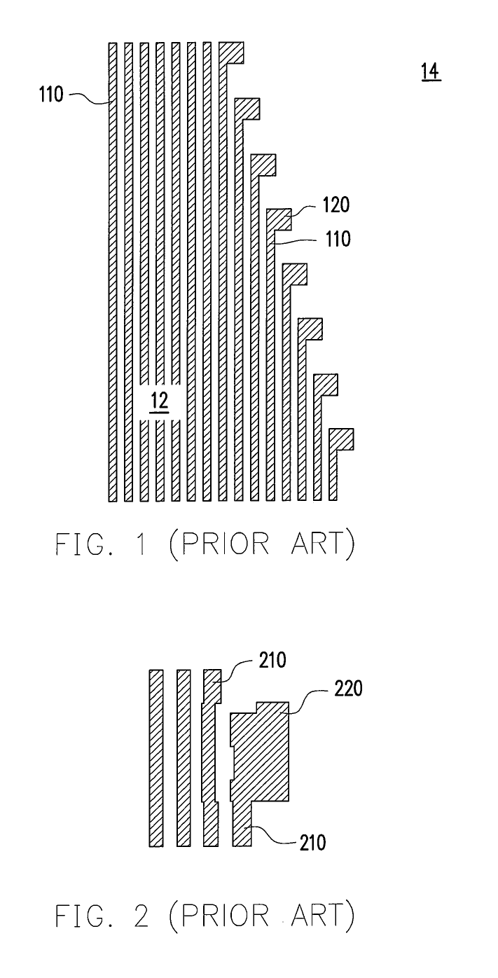

### DESCRIPTION OF THE EMBODIMENTS

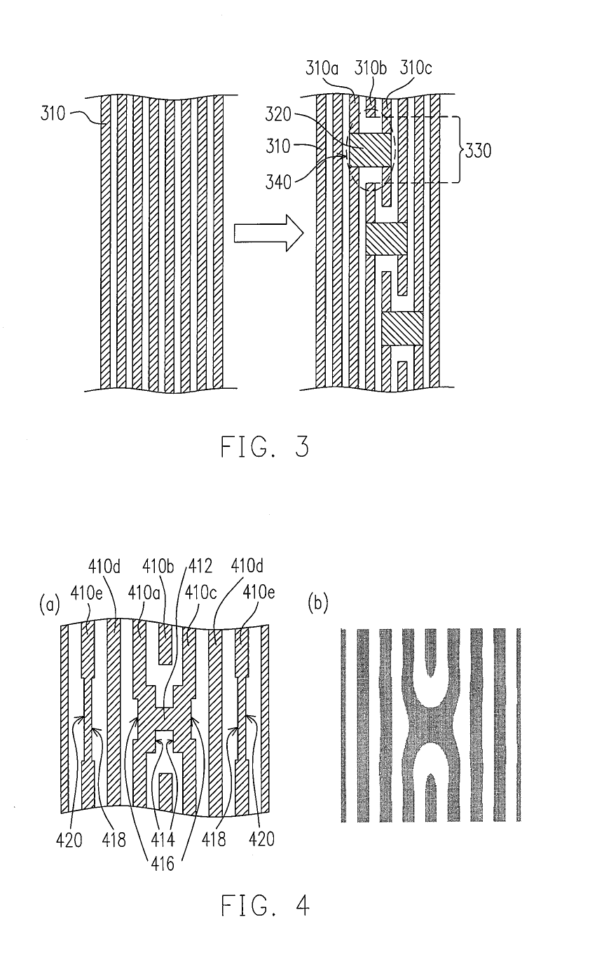

FIG. 3 shows a structure and a design process of a plurality of line patterns disposed with pickup pad patterns according to an embodiment of this invention.

Referring to FIG. 3, the patterns are designed in the following way. First, a plurality of line patterns 310 in parallel is defined, which includes photomask patterns of the lines that need to be disposed with pickup pads, and linear patterns acting as dummy patterns that do not need to be disposed with pickup pad patterns, i.e., the rightmost three linear patterns in the drawing. The dummy patterns cause a symmetric pattern arrangement so that the OPC is easier to perform.

Next, a pickup pad pattern 320 is disposed with the pattern 310 of each line that needs to be disposed with a pickup pad, and a discontinuity 330 is disposed at a position of the neighboring line pattern 310 corresponding to the pickup pad pattern 320. Taking the line pattern 310a that needs to be disposed with a pickup pad as an example, the pickup pad pattern 320 thereof is connected, through the discontinuity 330 of the neighboring line pattern 310b at one side of the line pattern 310a, to a next line pattern 310c so that an H-cut structure 340 is formed. It is noted that the neighboring line pattern 310b is not connected to the pickup pad pattern 320 of the line pattern 310a.

Referring to FIG. 3, if the process linewidth is large enough, with the photomask patterns as shown in the drawing, a circuit structure with a similar shape can be defined, which includes a plurality of lines in parallel corresponding to the line patterns 310 and a plurality of pickup pads corresponding to the pickup pad patterns 320. A part of the lines arranged contiguously are each disposed with a pickup pad, and the pickup pad of any line disposed with a pickup pad is connected, through a discontinuity of a neighboring line at one side of the line, to a next line so that an H-cut structure corresponding to the H-cut structure 340 on the photomask is formed.

However, when the linewidth is smaller, the line patterns 310 and the pickup pad patterns 320 may be further corrected through OPC. As compared with the dog-bone structure, the H-cut structure has a good symmetry and a more uniform pattern density around, so that its OPC can be symmetric OPC that is easier to implement. As known from computer simulations, a desirable effect can be obtained by merely performing manual OPC to the H-cut structure without computer-assisted correction.

Specifically, the H-cut pattern on the photomask can be corrected with partial cutting and/or other pattern correction manners such that the image of the H-cut pattern satisfies the specifications under proper focus/exposure conditions and certain condition variations, so as to ensure a sufficiently large process window.

FIG. 4 shows an example (a) of the OPC for forming a photomask pattern with an H-cut structure of this invention, and a computer simulation (b) of a circuit structure defined by the photomask pattern having been corrected through the OPC.

Referring to FIG. 4(a), the pickup pad defining pattern 412 is for defining the pickup pad of the line defined by the line pattern 410a, and is connected, through a discontinuity of a neighboring line pattern 410b, to a next line pattern 410c. The OPC process includes the following steps: reducing the dimension of the pickup pad defining pattern 412 in the extending direction of the line patterns, making the two inner boundaries 414 and the two outer boundaries 416 of two parts of the next line pattern 410c and the line pattern 410a respectively located at two sides of the pickup pad defining pattern 412 respectively protrude outwards and shrink inwards, and making the two inner boundaries 418 and the two outer boundaries 420 of two parts of the two line patterns 410e at the outer sides of the two line patterns 410d at the outer sides of the next line pattern 410c and the line pattern 410a respectively located at two sides of the pickup pad defining pattern 412 both shrink inwards. The pattern transfer result of the post-OPC pattern obtained through computer simulation is shown in FIG. 4(b), wherein the linewidth is set as 0.25 μm and the wavelength of the exposure light as 193 nm.

To sum up, in the H-cut structure of this invention, the pattern density around a pickup pad approaches that of the dense region, so that the optical proximity effect is easier to control as compared with the conventional dog-bone design. Furthermore, as the H-cut structure has a good symmetry, OPC is easier to implement. Through computer simulations and experiments, it is discovered that under the same condition of lithography process, the H-cut pattern design of this invention can make a process window larger than that made by the dog-bone pattern design.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A circuit structure, comprising a plurality of lines in parallel and a plurality of pickup pads, wherein
a part of the lines arranged contiguously are each disposed with a pickup pad; and
the pickup pad of any line disposed with a pickup pad is connected, through a discontinuity of a neighboring line at one side of the line, to a next line.

2. A photomask, comprising a plurality of line patterns in parallel and a plurality of pickup pad defining patterns, wherein
a part of the line patterns arranged contiguously are each disposed with a pickup pad defining pattern; and
the pickup pad defining pattern of any line pattern disposed with a pickup pad defining pattern is disposed, through a discontinuity of a neighbouring line pattern at one side of the line pattern, between a next line pattern and the line pattern.

3. The photomask according to claim 2, wherein the line patterns and the pickup pad defining patterns have been corrected through optical proximity correction (OPC).

4. The photomask according to claim 3, wherein the OPC is symmetric OPC.

5. The photomask according to claim 4, wherein the pickup pad defining pattern connects with the next line pattern and the line pattern.

6. The photomask according to claim 5, wherein the OPC related to the pickup pad defining patterns comprises:
reducing a dimension of the pickup pad defining pattern in an extending direction of the line patterns;
making two inner boundaries and two outer boundaries of two parts of the next line pattern and the line pattern respectively located at two sides of the pickup pad defining pattern respectively protrude outwards and shrink inwards; and
making two inner boundaries and two outer boundaries of two parts of two line patterns at outer sides of two line patterns at outer sides of the next line pattern and the line pattern respectively located at the two sides of the pickup pad defining pattern both shrink inwards.
